(19) United States
(12) Patent Application Publication
(10) Pub. No.: US 2026/0372184 A1
(43) Pub. Date: Nov. 19, 2026

(54) PACKAGE STRUCTURES AND METHODS FOR PREPARING THE SAME

(71) Applicant: Yangtze Memory Technologies Co., Ltd., Wuhan (CN)

(72) Inventors: Yun Xiang, Wuhan (CN); Baohua Zhang, Wuhan (CN)

(21) Appl. No.: 19/374,784

(22) Filed: Oct. 30, 2025

(30) Foreign Application Priority Data
May 19, 2025 (CN) 202510647486.6

(51) Int. Cl. H10W 90/00; H10B 80/00; H10D 80/30; H10W 70/60; H10W 72/00; H10W 90/24

(52) U.S. Cl. CPC H10W 90/00; H10B 80/00; H10D 80/30; H10W 70/611; H10W 90/401; H10W 90/701; H10W 72/075; H10W 90/24; H10W 90/724; H10W 90/752; H10W 90/754

(57) ABSTRACT

Implementations provide package structures and methods for preparing the same. A package structure includes: a substrate; a first stack disposed above the substrate and comprising a plurality of first dies, the first stack being connected to the substrate via a first wire; a connection structure disposed above the first stack and connected to the substrate via a second wire; and a second stack disposed above the connection structure and comprising a plurality of second dies. The second stack is connected to the connection structure via a third wire.

### CROSS-REFERENCE TO RELATED APPLICTAIONS

This application claims the benefit of priority to Chinese Application No. 202510647486.6, filed on May 19, 2025, which is hereby incorporated by reference in its entirety.

### FIELD

The present disclosure relates to package structures and methods for preparing the same.

### BACKGROUND

Stacks of dies (or chips) provided over a substrate are widely used in various electronic products. For example, stacks of memory dies may be used for memory devices, mobile phones, and the like.

As the integration of electronic products continues to increase, the number of dies in a stack is also rising. The increase in the number of dies in a stack may result in occupying more layout space on the substrate, potentially leading to insufficient layout space. With the increase in the number of dies in a stack, the risks of wire sweep, warpage, or failure in the Three-Point Bending (3PB) test are also increasing.

### SUMMARY

In one aspect, a package structure includes a substrate, a first stack, a connection structure, and a second stack. The first stack is disposed above the substrate and includes a plurality of first dies. The first stack is connected to the substrate via a first wire. The connection structure is disposed above the first stack and connected to the substrate via a second wire. The second stack is disposed above the connection structure and includes a plurality of second dies. The second stack is connected to the connection structure via a third wire.

In some implementations, the package structure further includes a first control die disposed above the substrate and connected to the substrate via a fourth wire. The first control die is configured to control the plurality of first dies and the plurality of second dies.

In some implementations, the package structure further includes a second control die disposed above the connection structure and connected to the connection structure via a fifth wire. The second control die is configured to control the plurality of first dies and the plurality of second dies.

In some implementations, the package structure further includes a first control die disposed above the substrate and connected to the substrate via a fourth wire; and a second control die disposed above the connection structure and connected to the connection structure via a fifth wire. The first control die is configured to control the plurality of first dies, and the second control die is configured to control the plurality of second dies.

In some implementations, the connection structure includes: a first layer including a first surface and a second surface opposite to the first surface; one or more first pads disposed above the first surface of the first layer; one or more second pads disposed above the second surface of the first layer; and a connector extending through the first layer and connecting one of the one or more first pads and one of the one or more second pads.

In some implementations, the first layer includes at least one of a silicon layer, a glass fiber layer, an insulating compound layer, or an insulating polymer layer. In some implementations, the one or more first pads and the one or more second pads include metal.

In some implementations, the connection structure further includes a second layer disposed above the first layer. In some implementations, the first layer includes a silicon layer, and the second layer includes a solder resist layer. In some implementations, the one or more first pads and the one or more second pads include metal.

In some implementations, the plurality of first dies and the plurality of second dies include memory dies of the same type.

In some implementations, the plurality of first dies and the plurality of second dies include at least one of NAND dies, or DRAM dies.

In some implementations, the first stack includes 2ⁿ dies, in which n is a positive integer. In some implementations, the second stack includes 2m dies, in which m is a positive integer.

In some implementations, at least one of the first wire, the second wire, the third wire, the fourth wire, or the fifth wire includes a gold wire.

In some implementations, for each pair of adjacent first dies in the first stack, a portion of an upper first die extends beyond a lower first die in a first direction parallel to the substrate. For each pair of adjacent second dies in the second stack, a portion of an upper second die extends beyond a lower second die in a second direction opposite to the first direction.

In some implementations, the first stack includes a first set of first dies and a second set of first dies stacked above the first set of first dies. For each pair of adjacent first dies in each set of the first and second sets of first dies, a portion of an upper first die extends beyond a lower first die in a first direction parallel to the substrate. A portion of a lowest die of the second set of first dies extends beyond an uppermost die of the first set of first dies in a second direction opposite to the first direction. In some implementations, the second stack includes a first set of second dies and a second set of second dies stacked above the first set of second dies. For each pair of adjacent second dies in each set of the first and second sets of second dies, a portion of an upper second die extends beyond a lower second die in the second direction. A portion of a lowest die of the second set of second dies extends beyond an uppermost die of the first set of second dies in the first direction.

In another aspect, a package structure includes a substrate, a stack, a control die, and a connection structure. The stack is disposed above the substrate and includes a plurality of dies, and the stack is connected to the substrate via a first wire. The control die is disposed above the substrate. The connection structure is disposed above the stack and the control die, and the connection structure is connected to the substrate via a second wire and connected to the stack via a third wire. The control die is coupled to the plurality of dies and configured to control the plurality of dies.

In some implementations, the control die is connected to a pad of the connection structure via a bump.

In some implementations, the package structure further includes a spacer disposed between the substrate and the control die.

In some implementations, the control die is connected to a pad of the substrate via a bump.

In some implementations, the package structure further includes a spacer disposed between the control die and the connection structure.

In some implementations, the connection structure includes: a first layer including a first surface and a second surface opposite to the first surface; one or more first pads disposed above the first surface of the first layer; one or more second pads disposed above the second surface of the first layer; and a connector extending through the first layer and connecting one of the one or more first pads and one of the one or more second pads.

In some implementations, the first layer includes at least one of a silicon layer, a glass fiber layer, an insulating compound layer, or an insulating polymer layer. In some implementations, the one or more first pads and the one or more second pads include metal.

In some implementations, the connection structure further includes a second layer disposed above the first layer. In some implementations, the first layer includes a silicon layer, and the second layer includes a solder resist layer. In some implementations, the one or more first pads and the one or more second pads include metal.

In some implementations, the plurality of dies include memory dies of different types. In some implementations, the plurality of dies include at least one of NAND dies, or DRAM dies.

In some implementations, the stack includes 2n dies, in which n is a positive integer.

In some implementations, at least one of the first wire, the second wire, or the third wire includes a gold wire.

In still another aspect, a method for preparing a package structure includes: providing a substrate; disposing a first stack above the substrate, the first stack including a plurality of first dies; forming a first wire connecting the first stack and the substrate; disposing a connection structure above the first stack; disposing a second stack above the connection structure, the second stack including a plurality of second dies; forming a second wire connecting the connection structure and the substrate; and forming a third wire connecting the second stack and the connection structure.

In some implementations, the method for preparing a package structure further includes disposing a first control die above the substrate; and forming a fourth wire connecting the first control die and the substrate. The first control die is configured to control the plurality of first dies and the plurality of second dies.

In some implementations, the method for preparing a package structure further includes disposing a second control die above the connection structure; and forming a fifth wire connecting the second control die and the connection structure. The second control die is configured to control the plurality of first dies and the plurality of second dies.

In some implementations, the method for preparing a package structure further includes disposing a first control die above the substrate; forming a fourth wire connecting the first control die and the substrate; disposing a second control die above the connection structure; and forming a fifth wire connecting the second control die and the connection structure. The first control die is configured to control the plurality of first dies, and the second control die is configured to control the plurality of second dies.

In some implementations, the method for preparing a package structure further includes forming the connection structure by: providing a first layer, which includes a first surface and a second surface opposite to the first surface; forming one or more first pads above the first surface of the first layer; forming a connector extending through the first layer; and forming one or more second pads above the second surface of the first layer. The connector connects one of the one or more first pads to one of the one or more second pads.

In yet another aspect, a method for preparing a package structure includes: providing a substrate; disposing a stack above the substrate, the stack including a plurality of dies; disposing a control die above one of the substrate or a connection structure; disposing the connection structure above the stack with the control die interposed between the substrate and the connection structure; forming a first wire connecting the stack and the substrate; forming a second wire connecting the connection structure and the substrate; and forming a third wire connecting the connection structure and the stack. The control die is coupled to the plurality of dies and configured to control the plurality of dies.

In some implementations, disposing the control die above one of the substrate or the connection structure includes forming a bump above the control die; and attaching a pad of the connection structure to the control die via the bump.

In some implementations, disposing the control die above one of the substrate or the connection structure includes forming a bump above the control die; and attaching a pad of the substrate to the control die via the bump.

Other features of the present disclosure and advantages thereof will become apparent from the following detailed description of exemplary implementations of the present disclosure with reference to the accompanying drawings.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a side view of a cross-section of an exemplary package structure, according to some aspects of the present disclosure.

FIG. 2 illustrates a side view of a cross-section of another exemplary package structure, according to some aspects of the present disclosure.

FIG. 3 illustrates a side view of a cross-section of still another exemplary package structure, according to some aspects of the present disclosure.

FIG. 4 illustrates a side view of a cross-section of yet another exemplary package structure, according to some aspects of the present disclosure.

FIG. 5A illustrates a side view of a cross-section of an exemplary connection structure, according to some aspects of the present disclosure.

FIG. 5B illustrates a side view of a cross-section of another exemplary connection structure, according to some aspects of the present disclosure.

FIG. 6 illustrates a flowchart of an exemplary method for preparing a package structure, according to some aspects of the present disclosure.

FIG. 7A illustrates a side view of a cross-section of an exemplary package structure, according to some aspects of the present disclosure.

FIG. 7B illustrates a side view of a cross-section of an exemplary module including a connection structure and a control die, according to some aspects of the present disclosure.

FIG. 8 illustrates a side view of a cross-section of another exemplary package structure, according to some aspects of the present disclosure.

FIG. 9 illustrates a flowchart of an exemplary method for preparing a package structure, according to some aspects of the present disclosure.

FIG. 10A illustrates a flowchart of an exemplary step for disposing a control die above a connection structure, according to some aspects of the present disclosure.

FIG. 10B illustrates a flowchart of an exemplary step for disposing a control die above a substrate, according to some aspects of the present disclosure.

Note that in the implementations described below, the same reference numerals are used in common between different drawings to denote the same portions or portions having the same functions, and a repetitive description thereof will be omitted. In this specification, like reference numerals and letters are used to designate like items, and therefore, once an item is defined in one drawing, further discussion thereof is not required in subsequent drawings.

For convenience of understanding, the positions, dimensions, ranges, and the like of the respective structures shown in the drawings and the like do not necessarily indicate actual positions, dimensions, ranges, and the like. The orientations shown in the drawings are merely illustrative. Therefore, the present disclosure shall not be limited to the positions, orientations, dimensions, ranges, etc. disclosed in the drawings and the like.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” may refer to a material onto which subsequent material layers are added. The substrate itself can be patterned. Materials added on top of the substrate can be patterned or can remain un-patterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” may refer to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

In stacks of dies within electronic products, the number of dies can influence the performance of the electronic products. For example, electronic products such as memory devices, mobile phones, and the like may include one or more stacks of memory dies. The greater the number of memory dies in the stack, the larger the memory capacity that the electronic product may have. Therefore, there is a tendency to increase the number of dies in stacks to enhance the performance of electronic products.

However, increasing the number of dies in a stack introduces several challenges. For example, the increase in the number of dies in a stack may result in occupying more layout space on the substrate, leading to insufficient layout space. The increase in the number of dies in the stack may also result in an increase in the stack height. As the stack height increases, the wires used for interconnection become longer. This leads to an increased distance between the wire landing points on the substrate and the edges of the dies, further exacerbating the issue of insufficient layout space. Longer wires may also increase the risk of wire sweep and complicate the wire bonding process. In addition, the increased stack height may also lead to an increased risk of warpage or failure in a 3PB test.

To address at least some of the aforementioned issues, the present disclosure provides solutions in which a connection structure is incorporated into the package structure that includes at least one stack of dies, in order to, for example, provide more layout space, improve the performance of wire bonding, and the like.

FIG. 1 illustrates a side view of a cross-section of an exemplary package structure 100, according to some aspects of the present disclosure.

As shown in FIG. 1, the package structure 100 can include a substrate 102, a first stack 110, a connection structure 130, and a second stack 120. The first stack 110 is disposed above the substrate 102 and includes a plurality of first dies 112. The first stack 110 is connected to the substrate 102 via a first wire 140. The connection structure 130 is disposed above the first stack 110 and is connected to the substrate 102 via a second wire 142. The second stack 120 is disposed above the connection structure 130 and includes a plurality of second dies 122. The second stack 120 is connected to the connection structure 130 via a third wire 144.

A person skilled in the pertinent art would readily understand that connecting or coupling two components through a wire may enable these components to be electrically interconnected, thereby allowing the exchange of electrical signals.

In some implementations, each first die 112 may be connected to at least one of the substrate 102 or other first dies (for example, an adjacent first die) through one or more corresponding wires. In some implementations, each second die 122 may be connected to at least one of the connection structure 130 or other second dies (for example, an adjacent second die) through one or more corresponding wires.

In some implementations, the plurality of first dies 112 and the plurality of second dies 122 may include memory dies of the same type.

In some implementations, the plurality of first dies 112 and the plurality of second dies 122 may include at least one of NAND dies, or DRAM dies.

The first stack 110 may include any number of first dies, and the second stack 120 may include any number of second dies. In some implementations, the first stack 110 may include 2ⁿ dies, in which n is a positive integer. The second stack 120 may include 2^{m} dies, in which m is a positive integer.

In some implementations, as shown in FIG. 1, for each pair of adjacent first dies 112 in the first stack 110, a portion of an upper first die may extend beyond a lower first die in a first direction (shown as -X direction in FIG. 1) parallel to the substrate 102. For each pair of adjacent second dies 122 in the second stack 120, a portion of an upper second die may extend beyond a lower second die in a second direction (shown as +X direction in FIG. 1) opposite to the first direction.

A person skilled in the pertinent art should understand that the stacking arrangement of the first and second dies schematically shown in FIG. 1 is merely illustrative and are not intended to be limiting. The stacking arrangement of the first and second dies in the package structure according to this disclosure may be freely selected and configured based on the requirements of the detailed applications.

In some implementations, the first stack 110 may include a first set of first dies and a second set of first dies stacked above the first set of first dies. For each pair of adjacent first dies in each set of the first and second sets of first dies, a portion of an upper first die extends beyond a lower first die in a first direction parallel to the substrate. A portion of the lowest die of the second set of first dies extends beyond the uppermost die of the first set of first dies in a second direction opposite to the first direction. The second stack 120 may include a first set of second dies and a second set of second dies stacked above the first set of second dies. For each pair of adjacent second dies in each set of the first and second sets of second dies, a portion of an upper second die extends beyond a lower second die in the second direction. A portion of the lowest die of the second set of second dies extends beyond the uppermost die of the first set of second dies in the first direction.

A person skilled in the pertinent art should understand that the number, arrangement, and connection relationship of the dies and the wires schematically shown in FIG. 1 are merely illustrative and are not intended to be limiting. The number, arrangement, and connection relationship of the dies and the wires in the package structure according to the present disclosure may be freely selected and configured based on the requirements of the detailed applications.

In some implementations, the package structure 100 may further include a first control die 150. As shown in FIG. 1, the first control die 150 is disposed above the substrate 102 and is connected to the substrate 102 via a fourth wire 146. The first control die 150 may be configured to control the plurality of first dies 112 and the plurality of second dies 122. A person skilled in the pertinent art should understand that the control die can be positioned either on the left side of the stack or on the right side of the stack.

In some implementations, as shown in FIG. 1, signals may be transmitted between the first control die 150 and the first dies 112 via a signal transmission path that includes the fourth wire 146, the substrate 102, and the first wire 140. For example, a control signal provided by the first control die 150 may be transmitted to a first die 112 via the signal transmission path. In another implementation, signals may be transmitted between the first control die 150 and the second dies 122 via a signal transmission path that includes the fourth wire 146, the substrate 102, the second wire 142, the connection structure 130, and the third wire 144. For example, a control signal provided by the first control die 150 may be transmitted to a second die 122 via the signal transmission path.

A person skilled in the pertinent art should understand that the arrangement of the control die schematically shown in FIG. 1 is merely illustrative and is not intended to be limiting. In some implementations, the package structure 100 may adopt a different arrangement of one or more control dies.

In one implementation, the package structure 100 may not include the first control die 150 but instead includes a second control die. The second control die may be disposed above the connection structure 130 and is connected to the connection structure 130 via a fifth wire. The second control die may be configured to control the plurality of first dies 112 and the plurality of second dies 122.

In one implementation, the package structure 100 may include the first control die 150 disposed above the substrate 102 and connected to the substrate 102 via a fourth wire 146; and also include a second control die disposed above the connection structure 130 and connected to the connection structure 130 via a fifth wire. The first control die 150 may be configured to control the plurality of first dies 112, and the second control die may be configured to control the plurality of second dies 122.

In some implementations, at least one of the first wire 140, the second wire 142, the third wire 144, the fourth wire 146, or the fifth wire may be made of a metal or alloy material. For example, at least one of the first wire 140, the second wire 142, the third wire 144, the fourth wire 146, or the fifth wire may include at least one of a gold (Au) wire, a copper (Cu) wire, an aluminum (Al) wire, and the like.

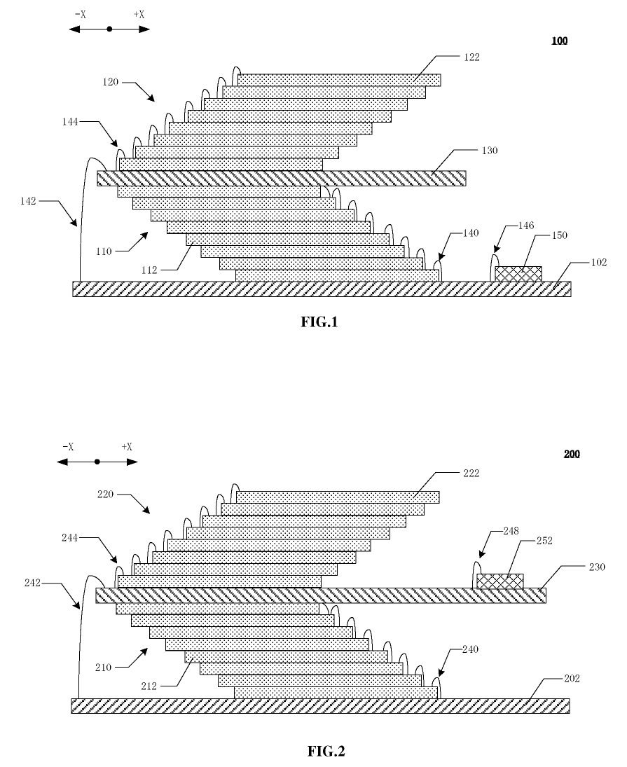

FIG. 2 illustrates a side view of a cross-section of another exemplary package structure 200, according to some aspects of the present disclosure.

As shown in FIG. 2, the package structure 200 can include a substrate 202, a first stack 210, a connection structure 230, and a second stack 220. The first stack 210 is disposed above the substrate 202 and includes a plurality of first dies 212. The first stack 210 is connected to the substrate 202 via a first wire 240. The connection structure 230 is disposed above the first stack 210 and is connected to the substrate 202 via a second wire 242. The second stack 220 is disposed above the connection structure 230 and includes a plurality of second dies 222. The second stack 220 is connected to the connection structure 230 via a third wire 244.

A person skilled in the pertinent art would readily understand that connecting or coupling two components through a wire may enable these components to be electrically interconnected, thereby allowing the exchange of electrical signals.

In some implementations, each first die 212 may be connected to at least one of the substrate 202 or other first dies (for example, an adjacent first die) through one or more corresponding wires. In some implementations, each second die 222 may be connected to at least one of the connection structure 230 or other second dies (for example, an adjacent second die) through one or more corresponding wires.

In some implementations, the plurality of first dies 212 and the plurality of second dies 222 may include memory dies of the same type.

In some implementations, the plurality of first dies 212 and the plurality of second dies 222 may include at least one of NAND dies, or DRAM dies.

The first stack 210 may include any number of first dies, and the second stack 220 may include any number of second dies. In some implementations, the first stack 210 may include 2ⁿ dies, in which n is a positive integer. The second stack 220 may include 2^{m} dies, in which m is a positive integer.

In some implementations, as shown in FIG. 2, for each pair of adjacent first dies 212 in the first stack 210, a portion of an upper first die may extend beyond a lower first die in a first direction (shown as -X direction in FIG. 2) parallel to the substrate 202. For each pair of adjacent second dies 222 in the second stack 220, a portion of an upper second die may extend beyond a lower second die in a second direction (shown as +X direction in FIG. 2) opposite to the first direction.

A person skilled in the pertinent art should understand that the stacking arrangement of the first and second dies schematically shown in FIG. 2 is merely illustrative and are not intended to be limiting. The stacking arrangement of the first and second dies in the package structure according to this disclosure may be freely selected and configured based on the requirements of the detailed applications. For example, the first stack may include more than two sets of first dies, or the second stack may include more than two sets of second dies.

In some implementations, the first stack 210 may include a first set of first dies and a second set of first dies stacked above the first set of first dies. For each pair of adjacent first dies in each set of the first and second sets of first dies, a portion of an upper first die extends beyond a lower first die in a first direction parallel to the substrate. A portion of the lowest die of the second set of first dies extends beyond the uppermost die of the first set of first dies in a second direction opposite to the first direction. The second stack 220 may include a first set of second dies and a second set of second dies stacked above the first set of second dies. For each pair of adjacent second dies in each set of the first and second sets of second dies, a portion of an upper second die extends beyond a lower second die in the second direction. A portion of the lowest die of the second set of second dies extends beyond the uppermost die of the first set of second dies in the first direction.

A person skilled in the pertinent art should understand that the number, arrangement, and connection relationship of the dies and the wires schematically shown in FIG. 2 are merely illustrative and are not intended to be limiting. The number, arrangement, and connection relationship of the dies and the wires in the package structure according to the present disclosure may be freely selected and configured based on the requirements of the detailed applications.

In some implementations, as shown in FIG. 2, the package structure may include a second control die 252, which is disposed above the connection structure 230 and is connected to the connection structure 230 via a fifth wire 248. The second control die 252 may be configured to control the plurality of first dies 212 and the plurality of second dies 222. A person skilled in the pertinent art should understand that the control die can be positioned either on the left side of the stack or on the right side of the stack.

In one implementation, signals may be transmitted between the second control die 252 and the first dies 212 via a signal transmission path that includes the fifth wire 248, the connection structure 230, the second wire 242, the substrate 202 and the first wire 240. In another implementation, signals may be transmitted between the second control die 252 and the second dies 222 via a signal transmission path that includes the fifth wire 248, the connection structure 230, and the third wire 244.

A person skilled in the pertinent art should understand that the arrangement of the control die schematically shown in FIG. 2 is merely illustrative and is not intended to be limiting. In some implementations, the package structure 200 may adopt a different arrangement of one or more control dies.

In one implementation, the package structure 200 may not include the second control die 252 but instead includes a first control die. The first control die may be disposed above the substrate 202 and is connected to the substrate 202 via a fourth wire. The first control die may be configured to control the plurality of first dies 212 and the plurality of second dies 222.

In one implementation, the package structure 200 may include a first control die disposed above the substrate 202 and connected to the substrate 202 via a fourth wire; and also include the second control die 252 disposed above the connection structure 230 and connected to the connection structure 230 via the fifth wire 248. The first control die may be configured to control the plurality of first dies 212, and the second control die 252 may be configured to control the plurality of second dies 222.

In some implementations, at least one of the first wire 240, the second wire 242, the third wire 244, the fourth wire, or the fifth wire 248 may be made of a metal or alloy material. For example, at least one of the first wire 240, the second wire 242, the third wire 244, the fourth wire or the fifth wire 248 may include at least one of a gold (Au) wire, a copper (Cu) wire, an aluminum (Al) wire, and the like.

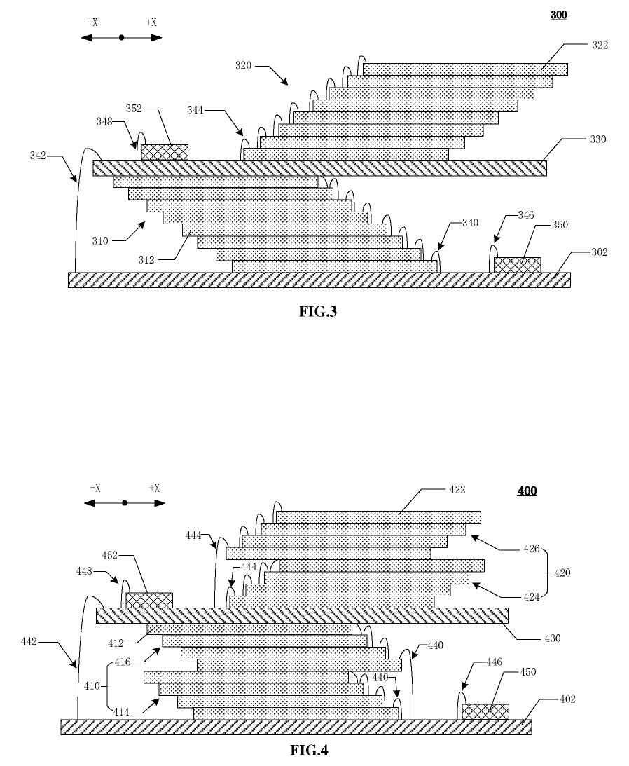

FIG. 3 illustrates a side view of a cross-section of still another exemplary package structure 300, according to some aspects of the present disclosure. As shown in FIG. 3, the package structure 300 can include a substrate 302, a first stack 310, a connection structure 330, and a second stack 320. The first stack 310 is disposed above the substrate 302 and includes a plurality of first dies 312. The first stack 310 is connected to the substrate 302 via a first wire 340. The connection structure 330 is disposed above the first stack 310 and is connected to the substrate 302 via a second wire 342. The second stack 320 is disposed above the connection structure 330 and includes a plurality of second dies 322. The second stack 320 is connected to the connection structure 330 via a third wire 344.

A person skilled in the pertinent art would readily understand that connecting or coupling two components through a wire may enable these components to be electrically interconnected, thereby allowing the exchange of electrical signals.

In some implementations, each first die 312 may be connected to at least one of the substrate 302 or other first dies (for example, an adjacent first die) through one or more corresponding wires. In some implementations, each second die 322 may be connected to at least one of the connection structure 330 or other second dies (for example, an adjacent second die) through one or more corresponding wires.

In some implementations, the plurality of first dies 312 and the plurality of second dies 322 may include memory dies of the same type.

In some implementations, the plurality of first dies 312 and the plurality of second dies 322 may include at least one of NAND dies, or DRAM dies.

The first stack 310 may include any number of first dies, and the second stack 320 may include any number of second dies. In some implementations, the first stack 310 may include 2ⁿ dies, in which n is a positive integer. The second stack 320 may include 2^{m} dies, in which m is a positive integer.

In some implementations, as shown in FIG. 3, for each pair of adjacent first dies 312 in the first stack 310, a portion of an upper first die may extend beyond a lower first die in a first direction (shown as -X direction in FIG. 3) parallel to the substrate 302. For each pair of adjacent second dies 322 in the second stack 320, a portion of an upper second die may extend beyond a lower second die in a second direction (shown as +X direction in FIG. 3) opposite to the first direction.

A person skilled in the pertinent art should understand that the stacking arrangement of the first and second dies schematically shown in FIG. 3 is merely illustrative and are not intended to be limiting. The stacking arrangement of the first and second dies in the package structure according to this disclosure may be freely selected and configured based on the requirements of the detailed applications. For example, the first stack may include more than two sets of first dies, or the second stack may include more than two sets of second dies.

In some implementations, the first stack 310 may include a first set of first dies and a second set of first dies stacked above the first set of first dies. For each pair of adjacent first dies in each set of the first and second sets of first dies, a portion of an upper first die extends beyond a lower first die in a first direction parallel to the substrate. A portion of the lowest die of the second set of first dies extends beyond the uppermost die of the first set of first dies in a second direction opposite to the first direction. The second stack 320 may include a first set of second dies and a second set of second dies stacked above the first set of second dies. For each pair of adjacent second dies in each set of the first and second sets of second dies, a portion of an upper second die extends beyond a lower second die in the second direction. A portion of the lowest die of the second set of second dies extends beyond the uppermost die of the first set of second dies in the first direction.

A person skilled in the pertinent art should understand that the number, arrangement, and connection relationship of the dies and the wires schematically shown in FIG. 3 are merely illustrative and are not intended to be limiting. The number, arrangement, and connection relationship of the dies and the wires in the package structure according to the present disclosure may be freely selected and configured based on the requirements of the detailed applications.

In some implementations, as shown in FIG. 3, the package structure 300 may include a first control die 350 disposed above the substrate 302 and connected to the substrate 302 via a fourth wire 346; and a second control die 352 disposed above the connection structure 330 and connected to the connection structure 330 via a fifth wire 348. The first control die 350 may be configured to control the plurality of first dies 312, and the second control die 352 may be configured to control the plurality of second dies 322.

A person skilled in the pertinent art should understand that each control die can be positioned either on the left side of the stack or on the right side of the stack. For example, the second control die can be positioned on the right side of the second stack, as shown in FIG. 2, or the second control die can be positioned on the left side of the second stack, as shown in FIG. 3.

In one implementation, signals may be transmitted between the second control die 352 and the second dies 322 via a signal transmission path that includes the fifth wire 348, the connection structure 330, and the third wire 344. In one implementation, signals may be transmitted between the first control die 350 and the first dies 312 via a signal transmission path that includes the fourth wire 346, the substrate 302, and the first wire 340.

A person skilled in the pertinent art should understand that the arrangement of the control dies schematically shown in FIG. 3 is merely illustrative and is not intended to be limiting. In some implementations, the package structure 300 may adopt a different arrangement of one or more control dies.

In one implementation, the package structure 300 may not include the second control die 352 but includes the first control die 350. The first control die 350 may be disposed above the substrate 302 and is connected to the substrate 302 via the fourth wire 346. The first control die may be configured to control the plurality of first dies 312 and the plurality of second dies 322.

In one implementation, the package structure 300 may not include the first control die 350 but includes the second control die 352. The second control die 352 may be disposed above the connection structure 330 and is connected to the connection structure 330 via the fifth wire 348. The second control die may be configured to control the plurality of first dies 312 and the plurality of second dies 322.

In some implementations, at least one of the first wire 340, the second wire 342, the third wire 344, the fourth wire 346, or the fifth wire 348 may be made of a metal or alloy material. For example, at least one of the first wire 340, the second wire 342, the third wire 344, the fourth wire 346, or the fifth wire 348 may include at least one of a gold (Au) wire, a copper (Cu) wire, an aluminum (Al) wire, and the like.

FIG. 4 illustrates a side view of a cross-section of yet another exemplary package structure 400, according to some aspects of the present disclosure.

As shown in FIG. 4, the package structure 400 can include a substrate 402, a first stack 410, a connection structure 430, and a second stack 420. The first stack 410 is disposed above the substrate 402 and includes a plurality of first dies 412. The first stack 410 is connected to the substrate 402 via a first wire 440. The connection structure 430 is disposed above the first stack 410 and is connected to the substrate 402 via a second wire 442. The second stack 420 is disposed above the connection structure 430 and includes a plurality of second dies 422. The second stack 420 is connected to the connection structure 430 via a third wire 444.

A person skilled in the pertinent art would readily understand that connecting or coupling two components through a wire may enable these components to be electrically interconnected, thereby allowing the exchange of electrical signals.

In some implementations, each first die 412 may be connected to at least one of the substrate 402 or other first dies (for example, an adjacent first die) through one or more corresponding wires. In some implementations, each second die 422 may be connected to at least one of the connection structure 430 or other second dies (for example, an adjacent second die) through one or more corresponding wires.

In some implementations, the plurality of first dies 412 and the plurality of second dies 422 may include memory dies of the same type.

In some implementations, the plurality of first dies 412 and the plurality of second dies 422 may include at least one of NAND dies, or DRAM dies.

The first stack 410 may include any number of first dies, and the second stack 420 may include any number of second dies. In some implementations, the first stack 410 may include 2ⁿ dies, in which n is a positive integer. The second stack 420 may include 2^{m} dies, in which m is a positive integer.

In some implementations, as shown in FIG. 4, the first stack 410 may include a first set of first dies 414 and a second set of first dies 416 stacked above the first set of first dies 414. For each pair of adjacent first dies 412 in each set of the first and second sets of first dies, a portion of an upper first die 412 extends beyond a lower first die 412 in a first direction (shown -X direction in FIG. 4) parallel to the substrate 402. A portion of the lowest die of the second set of first dies 416 extends beyond the uppermost die of the first set of first dies 414 in a second direction (shown +X direction in FIG. 4) opposite to the first direction.

In some implementations, the second stack 420 may include a first set of second dies 424 and a second set of second dies 426 stacked above the first set of second dies 424. For each pair of adjacent second dies 422 in each set of the first and second sets of second dies, a portion of an upper second die 422 extends beyond a lower second die 422 in the second direction. A portion of the lowest die of the second set of second dies 426 extends beyond the uppermost die of the first set of second dies 424 in the first direction.

A person skilled in the pertinent art should understand that the stacking arrangement of the first and second dies schematically shown in FIG. 4 is illustrative and is not intended to be limiting. The stacking arrangement of the first and second dies in the package structure according to this disclosure may be freely selected and configured based on the requirements of the detailed applications. For example, the first stack may include one set of first dies or more than two sets of first dies, or the second stack may include one set of second dies or more than two sets of second dies.

In some implementations, the fist stack 410 and the second stack 420 may be arranged similar to the first stack 110 and the second stack 120 shown in FIG. 1 respectively. In one implementation, for each pair of adjacent first dies in the first stack 410, a portion of an upper first die may extend beyond a lower first die in the first direction parallel to the substrate 402. For each pair of adjacent second dies in the second stack 420, a portion of an upper second die may extend beyond a lower second die in the second direction opposite to the first direction.

A person skilled in the pertinent art should understand that the number, arrangement, and connection relationship of the dies and the wires schematically shown in FIG. 4 are merely illustrative and are not intended to be limiting. The number, arrangement, and connection relationship of the dies and the wires in the package structure according to the present disclosure may be freely selected and configured based on the requirements of the detailed applications.

In some implementations, as shown in FIG. 4, the package structure 400 may include a first control die 450 disposed above the substrate 402 and connected to the substrate 402 via a fourth wire 446; and a second control die 452 disposed above the connection structure 430 and connected to the connection structure 430 via a fifth wire 448. The first control die 450 may be configured to control the plurality of first dies 412, and the second control die 452 may be configured to control the plurality of second dies 422.

In one implementation, signals may be transmitted between the second control die 452 and the second dies 422 via a signal transmission path that includes the fifth wire 448, the connection structure 430, and the third wire 444. In one implementation, signals may be transmitted between the first control die 450 and the first dies 412 via a signal transmission path that includes the fourth wire 446, the substrate 402, and the first wire 440.

A person skilled in the pertinent art should understand that the arrangement of the control dies schematically shown in FIG. 4 is merely illustrative and is not intended to be limiting. In some implementations, the package structure 400 may adopt a different arrangement of one or more control dies.

In one implementation, the package structure 400 may not include the second control die 452 but includes the first control die 450. The first control die 450 may be disposed above the substrate 402 and is connected to the substrate 402 via the fourth wire 446. The first control die may be configured to control the plurality of first dies 412 and the plurality of second dies 422.

In one implementation, the package structure 400 may not include the first control die 450 but includes the second control die 452. The second control die 452 may be disposed above the connection structure 430 and is connected to the connection structure 430 via the fifth wire 448. The second control die may be configured to control the plurality of first dies 412 and the plurality of second dies 422.

In some implementations, at least one of the first wire 440, the second wire 442, the third wire 444, the fourth wire 446, or the fifth wire 448 may be made of a metal or alloy material. For example, at least one of the first wire 440, the second wire 442, the third wire 444, the fourth wire 446, or the fifth wire 448 may include at least one of a gold (Au) wire, a copper (Cu) wire, an aluminum (Al) wire, and the like.

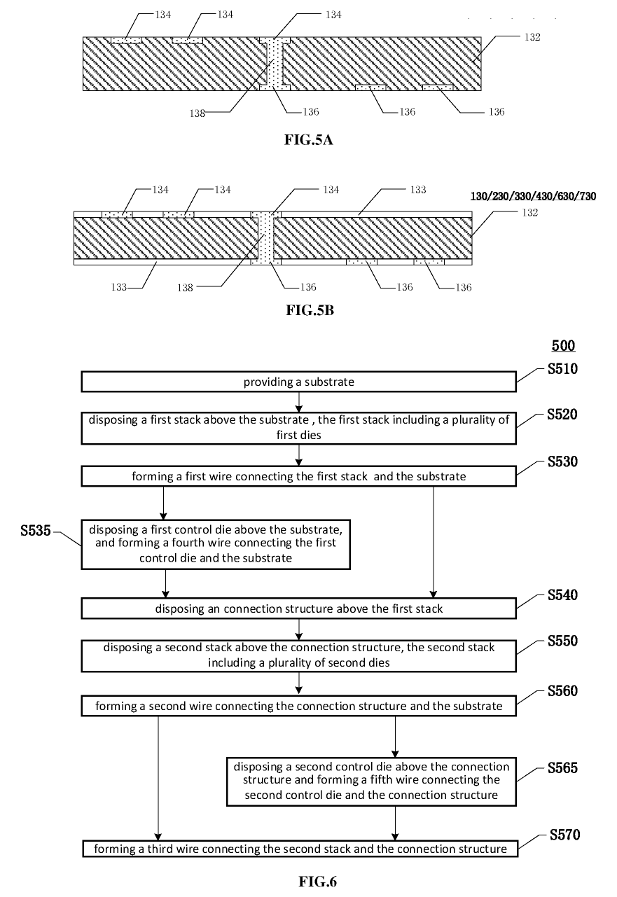

FIG. 5A illustrates a side view of a cross-section of an exemplary connection structure 130/230/330/430, according to some aspects of the present disclosure. As shown in FIG. 5A, the connection structure 130/230/330/430 may include a first layer 132 including a first surface and a second surface opposite to the first surface, one or more first pads 134, one or more second pads 136, and a connector 138. The one or more first pads 134 are disposed above the first surface of the first layer 132. The one or more second pads 136 are disposed above the second surface of the first layer 132. The connector 138 may extend through the first layer 132 and connect one of the one or more first pads 134 and one of the one or more second pads 136.

In some implementations, the first layer 132 may include at least one of a silicon layer, a glass fiber layer, an insulating compound layer, or an insulating polymer layer. In some implementations, the one or more first pads 134 and the one or more second pads 136 may include metal.

FIG. 5B illustrates a side view of a cross-section of another exemplary connection structure 130/230/330/430, according to some aspects of the present disclosure. As shown in FIG. 5B, when the first layer includes a silicon layer, the connection structure 130/230/330/430 may further include a second layer 133 disposed above the first layer, which may include a solder resist layer.

FIG. 6 illustrates a flowchart of an exemplary method 500 for preparing a package structure, according to some aspects of the present disclosure. The method 500 may be used for preparing the package structures 100, 200, 300, and 400 shown in FIGS. 1, 2, 3, and 4 respectively.

The method 500 may include, at step S510, providing a substrate; at step S520, disposing a first stack above the substrate, the first stack including a plurality of first dies; at step S530, forming a first wire connecting the first stack and the substrate; at step S540, disposing a connection structure above the first stack; at step S550, disposing a second stack above the connection structure, the second stack including a plurality of second dies; at step S560, forming a second wire connecting the connection structure and the substrate; and at step S570, forming a third wire connecting the second stack and the connection structure.

In some implementations, the method may optionally include, at step S535, disposing a first control die above the substrate and forming a fourth wire connecting the first control die and the substrate. The first control die may be configured to control the plurality of first dies and the plurality of second dies. In some implementations, step S535 may be performed at any time after step S510 and before step S540, for example, after step S510 and before step S520, after step S520 and before step S530, after step S530 and before step S540, or in at least partial parallel with steps S520 and S530, and the like. For example, when using the method 500 for preparing the package structure 100 in FIG. 1, the method may include step S535.

In some implementations, the method 500 may optionally include, at step S565, disposing a second control die above the connection structure and forming a fifth wire connecting the second control die and the connection structure. The second control die may be configured to control the plurality of first dies and the plurality of second dies. In some implementations, the step S565 may be performed at any time after step S540, for example, after step S540 and before step S550, after step S550 and before step S560, after step S560 and before step S570, or in at least partial parallel with steps S550, S560, and S570, and the like. For example, when using the method 500 for preparing the package structure 200 in FIG. 2, the method may include step S565.

In some implementations, the method 500 may optionally include: at step S535, disposing a first control die above the substrate and forming a fourth wire connecting the first control die and the substrate; and at step S565, disposing a second control die above the connection structure and forming a fifth wire connecting the second control die and the connection structure. The first control die may be configured to control the plurality of first dies, and the second control die may be configured to control the plurality of second dies. For example, when using the method 500 for preparing the package structure 300 in FIG. 3 or the package structure 400 in FIG. 4, the method may include both step S535 and step S565.

A person skilled in the pertinent art will understand that, based on the arrangement of one or more control dies, the method 500 for preparing the package structure may include step S535 without including step S565, may include step S565 without including step S535, or may include both step S535 and step S565.

In some implementations, the method 500 may optionally include forming the connection structure by: providing a first layer, which includes a first surface and a second surface opposite to the first surface; forming one or more first pads above the first surface of the first layer; forming a connector extending through the first layer; and forming one or more second pads above the second surface of the first layer. The connector may connect one of the one or more first pads to one of the one or more second pads.

According to various implementations, by providing a connection structure within the package structure, a stack containing a relatively large number of dies may be divided into at least two stacks containing a relatively smaller number of dies, thereby reducing the stack height. On one hand, the reduced stack height may decrease the length of the wires used for connection, thus lowering the risk of wire sweep and reducing the difficulties in the wire bonding process. The reduced length of the wires may also decrease the distance between the wire landing points on the substrate and the edges of the dies, thereby reducing the layout space occupied by the wires. On the other hand, the reduction in stack height, along with the appropriate pressure applied by the connection structure on the stack, reduces the risk of warpage or failure in a 3PB test. The reduced risk further decreases the difficulty of manufacturing the package structure and increases the yield of the product.

Further, according to various implementations, the connection structure may intuitively increase the layout space within the package structure, thus avoiding the issue of insufficient layout space and providing more flexibility for arranging various dies and wires. The connection structure may also provide additional routing space, for example, by connecting components located above the connection structure with components located below it via connectors. This not only improves the electrical connection performance but also allows for better utilization of the internal space of the package structure, thereby promoting the miniaturization process of the entire package structure.

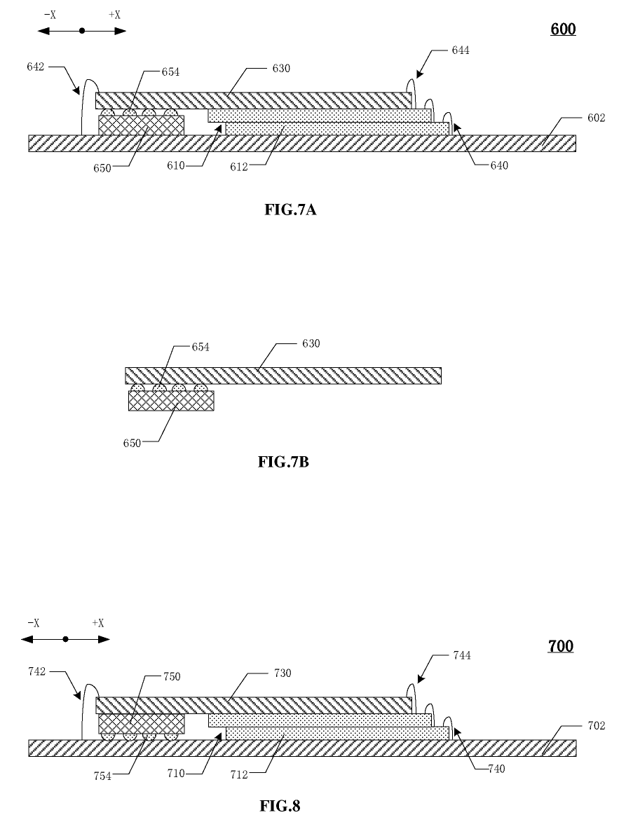

FIG. 7A illustrates a side view of a cross-section of an exemplary package structure 600, according to some aspects of the present disclosure. As shown in FIG. 7A, the package structure 600 may include a substrate 602, a stack 610, a control die 650, and a connection structure 630. The stack 610 is disposed above the substrate 602 and includes a plurality of dies 612. The stack 610 is connected to the substrate 602 via a first wire 640. The control die 650 is also disposed above the substrate 602. The connection structure 630 is disposed above the stack 610 and the control die 650. The connection structure 630 is connected to the substrate 602 via a second wire 642 and is connected to the stack 610 via a third wire 644. The control die 650 is coupled to the plurality of dies 612 and is configured to control the plurality of dies 612, for example, by transmitting a control signal to them.

A person skilled in the pertinent art would readily understand that connecting or coupling two components through a wire may enable these components to be electrically interconnected, thereby allowing the exchange of electrical signals.

In some implementations, the control die 650 and the stack 610 may be positioned on and in contact with a first surface of the substrate 602. The control die 650 and the stack 610 may be arranged in the +X direction as shown in FIG. 7A, and they can either be adjacent to each other or have one or more other components arranged between them.

In some implementations, each die 612 may be connected to at least one of the substrate 602 or other dies 612 (for example, an adjacent die 612) through one or more corresponding wires.

In some implementations, the plurality of dies 612 include memory dies 612 of different types. For example, the plurality of dies 612 may include at least one of NAND dies, or DRAM dies.

In some implementations, the stack 610 may include 2ⁿ dies 612, in which n is a positive integer.

In some implementations, at least one of the first wire 640, the second wire 642, or the third wire 644 may be made of a metal or alloy material. For example, at least one of the first wire 640, the second wire 642, or the third wire 644 may include at least one of a gold (Au) wire, a copper (Cu) wire, an aluminum (Al) wire, and the like.

In some implementations, as shown in FIG. 7A, for each pair of adjacent dies 612 in the stack 610, a portion of an upper first die may extend beyond a lower first die in a first direction (shown as -X direction in FIG. 7A) parallel to the substrate 102.

A person skilled in the pertinent art should understand that the stacking arrangement of the dies schematically shown in FIG. 7A is merely illustrative and are not intended to be limiting. The stacking arrangement of the dies in the package structure according to this disclosure may be freely selected and configured based on the requirements of the detailed applications.

In some implementations, the stack 610 may include a first set of dies and a second set of dies stacked above the first set of dies. For each pair of adjacent dies in each set of the first and second sets of dies, a portion of an upper first die extends beyond a lower first die in a first direction parallel to the substrate. A portion of the lowest die of the second set of dies extends beyond the uppermost die of the first set of dies in a second direction opposite to the first direction.

In some implementations, the control die 650 may be disposed above the connection structure 630 in a flip-chip configuration. For example, as shown in FIG. 7A, the control die 650 may be connected to one or more pads of the connection structure 630 via one or more bumps 654.

In some implementations, when the control die 650 is disposed above the connection structure 630 in a flip-chip configuration, the package structure 600 may further include a spacer disposed between the substrate 602 and the control die 650.

In some implementations, the connection structure 630 and the control die 650 disposed above the connection structure 630 may be fabricated in a modular manner. FIG. 7B illustrates a side view of a cross-section of an exemplary module including a connection structure and a control die, according to some aspects of the present disclosure.

As shown in FIG. 7B, this module may include the connection structure 630 and the control die 650 disposed above the connection structure 630 in a flip-chip configuration. For example, as shown in FIG. 7B, the control die 650 may be connected to one or more pads of the connection structure 630 via one or more bumps 654.

In some implementations, since the same control die may be adapted for different stacks of dies (for example, stacks of memory dies), the module including the connection structure and the control die, as illustrated in FIG. 7B, may be mass-produced to enhance manufacturing efficiency. Furthermore, components installed in a flip-chip configuration have a smaller bump pitch, and by producing the module including the connection structure and the control die in a fixed arrangement through a modular manner, the risk of shorts or non-wetting issues arising from the smaller bump pitch of the flip-chip configuration can be reduced.

A person skilled in the pertinent art should understand that the number, arrangement, and connection relationship of the dies and the wires schematically shown in FIGS. 7A and 7B are merely illustrative and are not intended to be limiting. The number, arrangement, and connection relationship of the dies and the wires in the package structure according to this disclosure may be freely selected and configured based on the requirements of the detailed applications.

FIG. 8 illustrates a side view of a cross-section of another exemplary package structure 700, according to some aspects of the present disclosure. As shown in FIG. 8, the package structure 700 may include a substrate 702, a stack 710, a control die 750, and a connection structure 730. The stack 710 is disposed above the substrate 702 and includes a plurality of dies 712. The stack 710 is connected to the substrate 702 via a first wire 740. The control die 750 is also disposed above the substrate 702. The connection structure 730 is disposed above the stack 710 and the control die 750. The connection structure 730 is connected to the substrate 702 via a second wire 742 and is connected to the stack 710 via a third wire 744. The control die 750 is coupled to the plurality of dies 712 and is configured to control the plurality of dies 712, for example, by transmitting a control signal to them.

A person skilled in the pertinent art would readily understand that connecting or coupling two components through a wire may enable these components to be electrically interconnected, thereby allowing the exchange of electrical signals.

In some implementations, the control die 750 and the stack 710 may be positioned on and in contact with a first surface of the substrate 702. The control die 750 and the stack 710 may be arranged in the +X direction shown in FIG. 8, and they can either be adjacent to each other or have one or more other components arranged between them.

In some implementations, each die 712 may be connected to at least one of the substrate 702 or other dies 712 (for example, an adjacent die 712) through one or more corresponding wires.

In some implementations, the plurality of dies 712 include memory dies 712 of different types. For example, the plurality of dies 712 may include at least one of NAND dies, or DRAM dies.

In some implementations, the stack 710 may include 2ⁿ dies 712, in which n is a positive integer.

In some implementations, at least one of the first wire 740, the second wire 742, or the third wire 744 may be made of a metal or alloy material. For example, at least one of the first wire 740, the second wire 742, or the third wire 744 may include at least one of a gold (Au) wire, a copper (Cu) wire, an aluminum (Al) wire, and the like.

In some implementations, as shown in FIG. 8, for each pair of adjacent dies 712 in the stack 710, a portion of an upper first die may extend beyond a lower first die in a first direction (shown as -X direction in FIG. 8) parallel to the substrate 602.

A person skilled in the pertinent art should understand that the stacking arrangement of the dies schematically shown in FIG. 8 is merely illustrative and are not intended to be limiting. The stacking arrangement of the dies in the package structure according to this disclosure may be freely selected and configured based on the requirements of the detailed applications.

In some implementations, the stack 710 may include a first set of dies and a second set of dies stacked above the first set of dies. For each pair of adjacent dies in each set of the first and second sets of dies, a portion of an upper first die extends beyond a lower first die in a first direction parallel to the substrate. A portion of the lowest die of the second set of dies extends beyond the uppermost die of the first set of dies in a second direction opposite to the first direction.

In some implementations, the control die 750 may be disposed above the substrate 702 in a flip-chip configuration. For example, as shown in FIG. 8, the control die 750 is connected to one or more pads of the substrate 702 via one or more bumps 754.

In some implementations, when the control die 750 is disposed above the substrate 702 in a flip-chip configuration, the package structure 700 may further include a spacer disposed between the control die 750 and the connection structure 730.

A person skilled in the pertinent art should understand that the number, arrangement, and connection relationship of the dies and the wires schematically shown in FIG. 8 are merely illustrative and are not intended to be limiting. The number, arrangement, and connection relationship of the dies and the wires in the package structure according to this disclosure may be freely selected and configured based on the requirements of the detailed applications.

In some implementations, the connection structure 630/730 has the same structure as the connection structure shown in FIG. 5A or FIG. 5B.

In some implementations, as shown in FIG. 5A, the connection structure 630/730 may include a first layer 132 including a first surface and a second surface opposite to the first surface, one or more first pads 134, one or more second pads 136, and a connector 138. The one or more first pads 134 are disposed above the first surface of the first layer 132. The one or more second pads 136 are disposed above the second surface of the first layer 132. The connector 138 may extend through the first layer 132 and connect one of the one or more first pad 134 and one of the one or more second pads 136.

In some implementations, the first layer 132 may include at least one of a silicon layer, a glass fiber layer, an insulating compound layer, or an insulating polymer layer. In some implementations, the one or more first pads 134 and the one or more second pads 136 may include metal.

In some implementations, as shown in FIG. 5B, when the first layer includes a silicon layer, the connection structure 130 may further include a second layer disposed above the first layer and including a solder resist layer.

FIG. 9 illustrates a flowchart of an exemplary method 800 for preparing a package structure, according to some aspects of the present disclosure. For example, the method 800 may be used for preparing the package structures 600 and 700 shown in FIGS. 7 and 8.

As shown in FIG. 9, the method 800 may include: at step S810, providing a substrate; at step S820, disposing a stack above the substrate, the stack including a plurality of dies; at step S830, disposing a control die above one of the substrate or a connection structure; at step S840, disposing the connection structure above the stack with the control die interposed between the substrate and the connection structure; at step S850, forming a first wire connecting the stack and the substrate; at step S860, forming a second wire connecting the connection structure and the substrate; and at step S870, forming a third wire connecting the connection structure and the stack. The control die is coupled to the plurality of dies and is configured to control the plurality of dies.

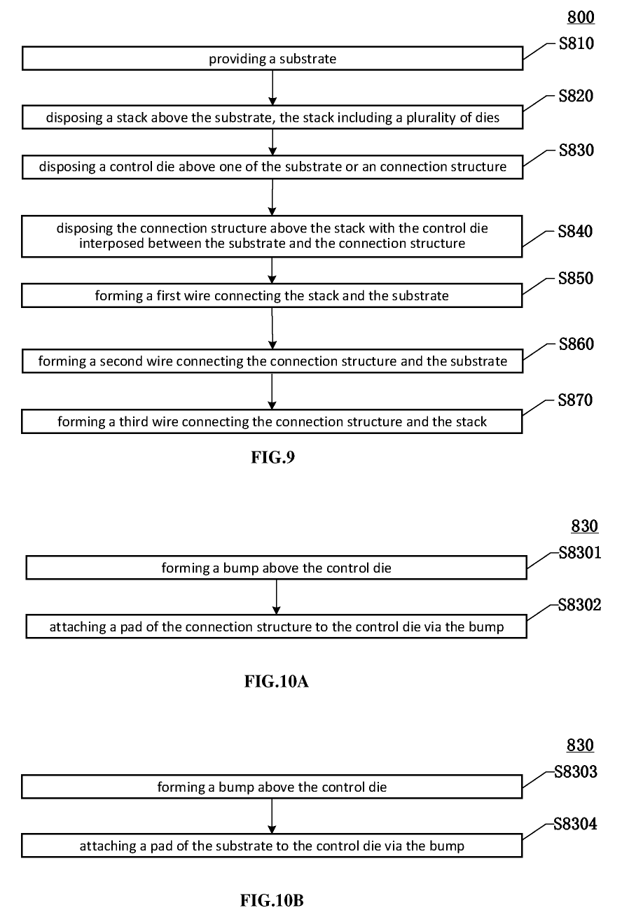

FIG. 10A illustrates a flowchart of an exemplary step S830 for disposing a control die above the connection structure, according to some aspects of the present disclosure. As shown in FIG. 10A, the step S830 may include, at step S8301, forming a bump above the control die; and at step S8302, attaching a pad of the connection structure to the control die via the bump. For example, when using the method 800 for preparing the package structure 600 in FIG. 7A, the step 430 may include step S8301 step S8302.

FIG. 10B illustrates a flowchart of an exemplary step S830 for disposing a control die above the substrate, according to some aspects of the present disclosure. As shown in FIG. 10B, the step S830 may include, at step S8303, forming a bump above the control die; and at step S8304, attaching a pad of the substrate to the control die via the bump. For example, when using the method 800 for preparing the package structure 700 in FIG. 8, the step S830 may include step S8303 step S8304.

According to various implementations, providing a connection structure within the package structure can intuitively increase the layout space within the package structure, thus avoiding the issue of insufficient layout space and providing more flexibility for arranging various dies and wires. The connection structure can also provide additional routing space, for example, by connecting wires located above the connection structure with components located below it via connectors. This not only improves the electrical connection performance but also allows for better utilization of the internal space of the package structure, thereby promoting the miniaturization process of the entire package structure.

On the other hand, the connection structure and the substrate can sandwich the stack of dies in the middle, thereby reducing the risk of warpage or failure in a 3PB test. The reduced risk further decreases the difficulty of manufacturing the package structure and increases the yield of the product.

A person skilled in the pertinent art will appreciate that the boundaries between the operations (or steps) described in the above implementations are merely illustrative. Multiple operations may be combined into a single operation, single operation may be distributed in additional operations, and operations may be performed at least partially overlapping in time. Moreover, alternative implementations may include multiple instances of a particular operation, and the order of operations may be altered in various other implementations. However, other modifications, variations, and alternatives are also possible. The specification and drawings are, accordingly, to be regarded in an illustrative rather than a restrictive sense.

Although some specific implementations of the present disclosure have been described in detail by way of example, it should be understood by a person skilled in the pertinent art that the above examples are for illustration only and are not intended to limit the scope of the present disclosure. The various implementations disclosed herein may be combined arbitrarily without departing from the spirit and scope of the present disclosure. A person skilled in the pertinent art will also appreciate that various modifications may be made to the implementations without departing from the scope and spirit of the present disclosure. The scope of the present disclosure is defined by the appended claims.

What is claimed is:

1. A package structure comprising:
a substrate;
a first stack disposed above the substrate and comprising a plurality of first dies, the first stack being connected to the substrate via a first wire;
a connection structure disposed above the first stack and connected to the substrate via a second wire; and
a second stack disposed above the connection structure and comprising a plurality of second dies, wherein the second stack is connected to the connection structure via a third wire.

2. The package structure according to claim 1, further comprising:
a first control die disposed above the substrate and connected to the substrate via a fourth wire,
wherein the first control die is configured to control the plurality of first dies and the plurality of second dies.

3. The package structure according to claim 1, further comprising:
a first control die disposed above the substrate and connected to the substrate via a fourth wire; and
a second control die disposed above the connection structure and connected to the connection structure via a fifth wire,
wherein the first control die is configured to control the plurality of first dies, and the second control die is configured to control the plurality of second dies.

4. The package structure according to claim 1, wherein the connection structure comprises:
a first layer comprising a first surface and a second surface opposite to the first surface;
one or more first pads disposed above the first surface of the first layer;
one or more second pads disposed above the second surface of the first layer; and
a connector extending through the first layer and connecting one of the one or more first pads and one of the one or more second pads.

5. The package structure according to claim 4, wherein:
the first layer comprises at least one of a silicon layer, a glass fiber layer, an insulating compound layer, or an insulating polymer layer; and
the one or more first pads and the one or more second pads comprise metal.

6. The package structure according to claim 4, wherein:
the connection structure further comprises a second layer disposed above the first layer;
the first layer comprises a silicon layer;
the second layer comprises a solder resist layer; and
the one or more first pads and the one or more second pads comprise metal.

7. The package structure according to claim 1, wherein the plurality of first dies and the plurality of second dies comprise memory dies of a same type.

8. The package structure according to claim 7, wherein the plurality of first dies and the plurality of second dies comprise at least one of NAND dies, or DRAM dies.

9. The package structure according to claim 1, wherein:
the first stack comprises 2ⁿ dies, n being a positive integer; and
the second stack comprises 2^{m} dies, m being a positive integer.

10. The package structure according to claim 1, wherein:
for each pair of adjacent first dies in the first stack, a portion of an upper first die extends beyond a lower first die in a first direction parallel to the substrate; and
for each pair of adjacent second dies in the second stack, a portion of an upper second die extends beyond a lower second die in a second direction opposite to the first direction.

11. The package structure according to claim 1, wherein:
the first stack comprises a first set of first dies and a second set of first dies stacked above the first set of first dies;
for each pair of adjacent first dies in each set of the first and second sets of first dies, a portion of an upper first die extends beyond a lower first die in a first direction parallel to the substrate;
a portion of a lowest die of the second set of first dies extends beyond an uppermost die of the first set of first dies in a second direction opposite to the first direction;
the second stack comprises a first set of second dies and a second set of second dies stacked above the first set of second dies;
for each pair of adjacent second dies in each set of the first and second sets of second dies, a portion of an upper second die extends beyond a lower second die in the second direction; and
a portion of a lowest die of the second set of second dies extends beyond an uppermost die of the first set of second dies in the first direction.

12. A package structure comprising:
a substrate;
a stack disposed above the substrate and comprising a plurality of dies, the stack being connected to the substrate via a first wire;
a control die disposed above the substrate; and
a connection structure disposed above the stack and the control die, the connection structure being connected to the substrate via a second wire and being connected to the stack via a third wire,
wherein the control die is coupled to the plurality of dies and configured to control the plurality of dies.

13. The package structure according to claim 12, wherein the control die is connected to a pad of the connection structure via a bump.

14. The package structure according to claim 12, wherein the control die is connected to a pad of the substrate via a bump.

15. The package structure according to claim 12, wherein the connection structure comprises:
a first layer comprising a first surface and a second surface opposite to the first surface;
one or more first pads disposed above the first surface of the first layer;
one or more second pads disposed above the second surface of the first layer; and
a connector extending through the first layer and connecting one of the one or more first pads and one of the one or more second pads.

16. The package structure according to claim 15, wherein:
the first layer comprises at least one of a silicon layer, a glass fiber layer, an insulating compound layer, or an insulating polymer layer; and
the one or more first pads and the one or more second pads comprise metal.

17. The package structure according to claim 12, wherein:
the plurality of dies comprise memory dies of different types; and
the plurality of dies comprise at least one of NAND dies, or DRAM dies.

18. A method for preparing a package structure, comprising:
providing a substrate;
disposing a first stack above the substrate, the first stack comprising a plurality of first dies;
forming a first wire connecting the first stack and the substrate;
disposing a connection structure above the first stack;
disposing a second stack above the connection structure, the second stack comprising a plurality of second dies;
forming a second wire connecting the connection structure and the substrate; and
forming a third wire connecting the second stack and the connection structure.

19. The method according to claim 18, further comprising:
disposing a first control die above the substrate; and
forming a fourth wire connecting the first control die and the substrate,
wherein the first control die is configured to control the plurality of first dies and the plurality of second dies.

20. The method according to claim 18, further comprising forming the connection structure by:
providing a first layer, wherein the first layer comprises a first surface and a second surface opposite to the first surface;
forming one or more first pads above the first surface of the first layer;
forming a connector extending through the first layer; and
forming one or more second pads above the second surface of the first layer,
wherein the connector connects one of the one or more first pads to one of the one or more second pads.
